(19) United States
(12) Patent Application Publication
(10) Pub. No.: US 2022/0025519 A1
(43) Pub. Date: Jan. 27, 2022

(54) DEPOSITION REACTOR WITH INDUCTORS AND ELECTROMAGNETIC SHIELDS

(71) Applicant: LPE S.P.A., Baranzate (MI) (IT)

(72) Inventors: Michele Forzan, Baranzate (MI) (IT); Danilo Crippa, Baranzate (MI) (IT); Silvio Preti, Baranzate (MI) (IT)

(21) Appl. No.: 17/277,222

(22) PCT Filed: Oct. 24, 2019
(86) PCT No.: PCT/IB2019/059127

§ 371 Date: Mar. 17, 2021

(51) Int. Cl. C23C 16/46; H05B 6/44

(52) U.S. Cl. CPC C23C 16/46; C30B 25/10; H05B 6/44

(57) ABSTRACT

The reactor (100) for deposition of layers of semiconductor material on substrates, comprises: a reaction chamber (110), a susceptor assembly (120) located inside the reaction chamber, and a heating system (130) adapted to heat the susceptor assembly by electromagnetic induction; the heating system (130) comprises a first (131) inductor and a second (132) inductor and a power supply (135) adapted to electrically feed the first and second inductors (131, 132) with alternating currents that are distinct and independent from one another; the reactor (100) further comprises a shielding assembly (140) adapted to limit electromagnetic coupling between the first and the second inductors (131, 132).

### FIELD OF THE INVENTION

The present invention concerns a reactor for deposition of layers of semiconductor material on substrates equipped with inductors and shields.

### STATE OF THE ART

The reaction chambers of reactors for deposition of layers of semiconductor material on substrates, sometimes called “semi”, need to be heated because the reaction temperature is high.

In these reactors, the reaction temperature can for example be 800-1200° C. in the case of epitaxial deposition of silicon, and for example 1600-3000° C. in the case of epitaxial deposition of silicon carbide; the result of the deposition can for example be a layer (more or less thick) or an ingot (i.e. a long crystal).

In order to obtain such heating, inside the reaction chamber it is possible to position a susceptor assembly adapted to be heated by electromagnetic induction, and outside of the reaction chamber it is possible to position an inductor adapted to generate a magnetic field for the heating of the susceptor assembly.

The susceptor assembly is typically made of graphite and can be variously shaped and variously composed to obtain the desired heating inside the reaction chamber. It should be noted that, in general, it may be preferable for the temperature to not be uniform inside the chamber; in particular, the desired temperature distribution inside the chamber can depend on the operative condition of the reactor.

The Applicant has concentrated on reaction chambers comprising a tube made of quartz and having a cylindrical shape; in particular, the Applicant has concentrated on chambers of large dimensions (for example diameter greater than 50 cm and height greater than 100 cm).

Such chambers have application, in particular, in reactors for the growth of ingots of silicon carbide from “seeds” at extremely high temperature, for example greater than 2000° C.

### SUMMARY

The general purpose of the present invention is to provide a reactor in which the temperature can be controlled well inside the reaction chamber. This general purpose is accomplished thanks to what is set out in the attached claims that form an integral part of the present description.

A first idea at the basis of the present invention is to use at least two inductors to heat the susceptor assembly.

A second idea at the basis of the present invention is to use a shielding assembly adapted to limit electromagnetic coupling between the two inductors so that it is easier to electrically control them independently from one another and thus control their heating effect independently from one another.

### LIST OF FIGURES

The present invention will be clearer from the following detailed description to be considered together with the attached drawings, in which:

FIG. 1 shows a very schematic and partial side section view of an embodiment of a reactor according to the present invention,

FIG. 2 shows a very schematic and partial view from above of the reactor of FIG. 1,

FIG. 3 schematically shows the lines of the magnetic field of a solenoid,

FIG. 4 schematically shows the lines of the magnetic field of the solenoid of FIG. 3 associated with a shield according to the present invention, and

FIG. 5 shows a three-dimensional view of an assembly partially sectioned according to the present invention that could constitute a component of the reactor of FIG. 1.

As can easily be understood, there are various ways to practically implement the present invention that is defined in its main advantageous aspects in the attached claims and is not limited either by the following detailed description or by the attached drawings.

### DETAILED DESCRIPTION

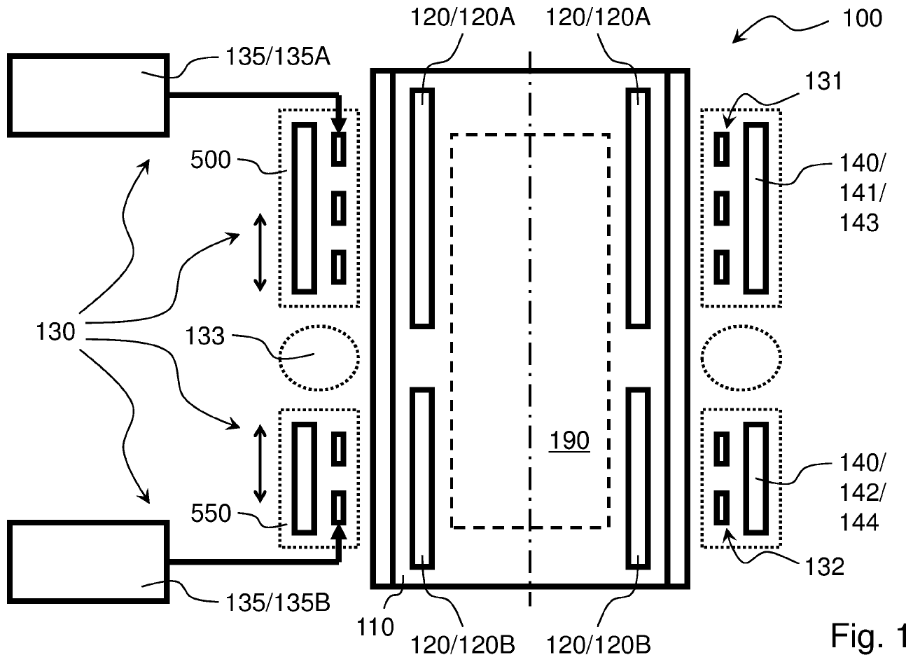

FIG. 1 shows a reaction chamber 110 of a reactor 100 with a susceptor assembly 120 inside. The side walls of the chamber 110 consist in particular of a tube made of quartz and having a cylindrical shape; the axis of the tube is arranged vertically, but it could also be arranged differently, for example horizontally.

The reactor 100 also comprises a heating system 130 (to be interpreted as sub-system) adapted to heat the susceptor assembly 120 by electromagnetic induction.

It should be noted that the reaction chamber has been represented in FIG. 1 as a single tubular body for the sake of simplicity. However, typically, there is a first tube made of quartz and having a cylindrical shape; inside the first tube there is a second tube made of heat insulating material and having a cylindrical shape; inside the second tube there is a third tube made of graphite and having a cylindrical shape. Typically but not necessarily, the third tube is also adapted to be heated by electromagnetic induction by the heating system 130; thus, in a certain sense, the third tube could also be considered a component of the susceptor assembly of the reactor.

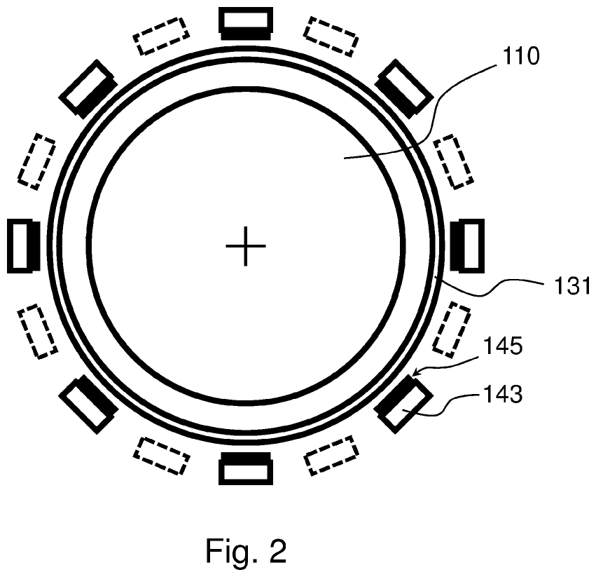

According to the example of FIG. 1 and FIG. 2, the heating system 130 consists of a first inductor 131 and a second inductor 132 and a power supply 135 adapted to electrically feed the inductors 131 and 132 with alternating currents that are distinct and independent from one another; in particular and as shown schematically in FIG. 1, the power supply 135 comprises a first feeding section 135A for feeding the first inductor 131 and a second feeding section 135B (distinct and independent from the first) for feeding the second inductor 132.

According to the example of FIG. 1 and FIG. 2, the susceptor assembly 120 consists of two tubular elements 120A and 120B made of graphite. In general, the susceptor assembly (to be interpreted as sub-system) can comprise one or more elements at least partially made of a conductive material adapted to couple with the magnetic field generated by the inductor or by the inductors of the heating system, to be crossed by electric current and to heat up by Joule effect. Such one or more elements can be variously configured and are located inside the reaction chamber. One or more of such elements can perform other functions, for example support one or more substrates.

FIG. 1 shows an inner reaction and deposition area 190; in the area 190 at least one substrate (not shown in the figure) is positioned, which is typically supported by a support element (not shown in the figure) that can be called “susceptor element” (as stated above) when the element has not only the function of supporting, but also that of heating the substrate. A (more or less thick) layer is deposited on the substrate during a so-called high-temperature “growth” process. FIG. 1 does not show any of the components inside the reaction chamber 110, with the exception of the susceptor assembly 120, not being relevant for the purposes of the present invention.

The use of many inductors makes it possible to better control the transfer of energy to the susceptor assembly and thus to more precisely control the heating thereof from the spatial point of view.

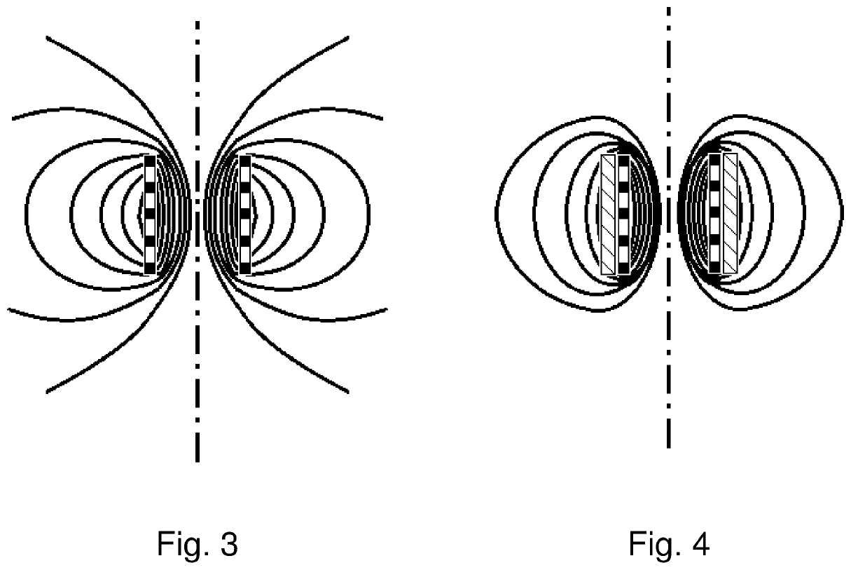

As can be seen in FIG. 1, the inductors 131 and 132 are a little spaced apart; such a distance is not necessarily fixed and can range for example from 5 cm to 50 cm; the space between the two inductors 131 and 132 is schematically indicated with reference numeral 133. However, such a distance does not avoid electromagnetic coupling between the two inductors. Indeed, for example in the case of a solenoid, the magnetic field (represented in FIG. 3) extends a great distance from the solenoid both in the radial direction and in the axial direction. In the example of FIG. 1 and FIG. 2, it is the axial extension of the magnetic fields generated by the inductors 131 and 132 when they are crossed by electric currents that cause electromagnetic coupling together.

If two inductors are electromagnetically coupled with each other, when one of the two is electrically fed energy (a little or a lot depending on the degree of coupling) is supplied indirectly also to the other of the two, and therefore it is as if not just one is electrically controlled but also the other. If the electromagnetic coupling between the two inductors 131 and 132 were limited it would be easier to electrically control them by the feeding sections 135A and 1358 independently from one another and thus control their heating effect on the susceptor assembly 120 independently from one another; if the coupling was absent, it would be even better.

In order to limit the electromagnetic coupling between the inductors of the heating system the present invention provides for a shielding assembly (to be interpreted as sub-system).

In FIG. 1 and FIG. 2, the reactor 100 comprises a shielding assembly 140 adapted to limit electromagnetic coupling between the inductors 131 and 132; the assembly 140 comprises in particular a first shield 141 and a second shield 142.

As can be seen in FIG. 1, the positioning of the shielding assembly 140 is counterintuitive. Indeed, having to shield the inductors 131 and 132, something suitable would normally be positioned in the space that separates them (indicated with 133 in FIG. 1). On the other hand, according to the preferred embodiments of the present invention, the shielding assembly is positioned laterally with respect to the inductors;

such positioning is possible because it has been thought of to use a property of some materials, i.e. the materials having high magnetic permeability (for example ferromagnetic materials are suitable for the purpose since they have a high magnetic permeability at least in certain conditions). According to such a property, when a piece of such material is immersed in a magnetic field it deforms it so that the lines of the magnetic field tend to concentrate inside the piece. FIG. 4 shows the magnetic field of the same solenoid of FIG. 3, but with the addition of a cylindrical tube for example of ferrite (radially) around the solenoid; the lines of the magnetic field are concentrated in the tube; as a result the magnetic field extends much less not only in the radial direction, but also in the axial direction, and therefore a shield the same as or similar to the tube of ferrite can be used to shield the inductors of the heating system of the reactor according to the present invention.

It should be noted that the property just described can be used to design shields having the shape not of a cylindrical tube and/or adapted to be arranged not around the solenoid; for example, a shield could have the shape of a perforated disc and be arranged (substantially) coaxial to the solenoid and (axially) beside the solenoid.

The material of the shielding assembly, more precisely of its shielding components (also called “shields”), is a material having high magnetic permeability, preferably relative magnetic permeability greater than 100, more preferably relative magnetic permeability greater than 500;
ferromagnetic materials are suitable for the purpose since they have a high magnetic permeability at least in certain conditions, i.e. when they are far from saturation.

For the purposes of the present invention, it is very preferable for the material of the shielding assembly, more precisely of its shielding components (also called “shields”), to be a material not only that has high magnetic permeability, but also high electrical resistivity, preferably resistivity greater than 1 ohm*mm2/m, more preferably resistivity greater than 10 ohm*mm2/m, even more preferably resistivity greater than 100 ohm*mm2/m. Indeed, if the material of a shield has high electrical resistivity, i.e. it is electrically insulating, the electrical currents induced in the shield are of limited intensity and therefore the electrical energy supplied by the power supply to the inductor transforms (partially) into electromagnetic energy that transfers to a large extent to the element of the susceptor assembly associated with the inductor and to a small extent to the shield associated with the inductor.

It should be noted that (at least) the electrical and magnetic properties of a piece of material depend not only on the substances that make up the material, but also on the way in which the piece is produced.

Materials particularly suitable for the shields according to the present invention (taking into account permeability, resistivity and cost) are, for example, ferrite and ferrosilicon (for example in the form of adjacent sheets).

In the example of FIG. 1 and FIG. 2, the shielding assembly 140 comprises a first shield 141 associated with the first inductor 131 and a second shield 142 associated with the second inductor 132. Said in more general terms, every inductor is associated with a shield that, it can be said, tends to confine (not confining in the narrow sense) the magnetic field generated by the inductor when it is crossed by electrical current in a certain surface; such a surface substantially corresponds to the outer surface of the shield (that in FIG. 4 is a cylindrical surface).

The inductors 131 and 132 are, in particular, solenoids; moreover, they are typically coaxial and axially spaced; finally, in the example of FIG. 1 and FIG. 2, the two solenoids have the same diameter.

In the example of FIG. 1 and FIG. 2, the solenoids 131 and 132 are adapted to be translated in the axial direction independently from one another; for this purpose, it is possible to provide, for example, an electric actuator to carry out the translation of an inductor. Such a possibility of translation makes it possible to influence the temperature profile inside the chamber 110. Such a translation can be carried out “every so often” as calibration of the reactor, but can also be carried out during the use of the reactor, for example during a heating and/or during a deposition process and/or during a cooling.

In the example of FIG. 1 and FIG. 2, as already stated, there is a first shield 141 associated with the first inductor 131 and a second shield 142 associated with the second inductor 132. It was preferred, since the inductors (131, 132) are adapted to translate, for the shields (141, 142) to also be adapted to translate together with the corresponding inductors (131, 132). In this way, the shielding action of the shields is always the same irrespective of the position of the inductors.

As explained earlier, the shielding assembly 140 is tubular in shape and is located around the solenoids 131 and 132, in particular one tubular shield around each solenoid.

According to a preferred embodiment, the insulation of a solenoid can be carried out through a plurality of bars of suitable material (described earlier) parallel to one another, in particular of square or rectangular section. Said differently, material has been eliminated from the (ideal) cylindrical tube; in this way, material is saved, weight is reduced, production is made easier and spaces remain through which it is possible to see not only the solenoid, but also the more inner areas of the reaction chamber, in particular the substrate and the layer in the deposition step (for example through X rays). FIG. 2 shows as an example eight bars with a solid line and another eight with a dashed line to indicate that the number of bars depends on their size, on the diameter of the solenoid (and therefore on the diameter of the reaction chamber); it is reasonable to deem a minimum number of six bars and a maximum number of sixty bars, but in the case of shaped bars (for example of arched section) the number could also be less.

In the example of FIG. 1 and FIG. 2, there is a first set of bars 143 for the first inductor 131 and a second set of bars 144 for the second inductor 132. According to an alternative, but less performing solution, it is possible for example to provide a single set of bars.

As can be seen in FIG. 2, it may be preferable for the bars of the shield to be associated with a layer of electrical insulating material; in the figure the layer is indicated with reference numeral 145. Such a layer is used to prevent the bars from being able to make electrical contact with the solenoid, precisely with the coils of the solenoid; such contact could be avoided by increasing the distance between bars and solenoid, however since it is preferable for the bars to be close to the solenoid, a layer is provided that can thus be limited to the side of the bars facing towards the inductor (in FIG. 2, the layer 135 on each of the bars 143 is limited to the side facing towards the inductor 131). It is worth observing that during operation, i.e. when the inductor is crossed by electric current and magnetic field is concentrated in the bars, forces develop on the bars in the direction of the coils and on the coils in the direction of the bars that tend to deform the bars and the coils so as to bring them together; moreover, such forces produce vibrations at double frequency to that of the electric current that flows in the inductor.

As can be seen in FIG. 1, the first shield 141 and the first inductor 131 are surrounded by a dotted line and associated to form a first assembly 500, and the second shield 142 and the second inductor 132 were surrounded by a dotted line and associated to form a second assembly 550; both the assembly 500 and the assembly 550 are adapted to translate axially along the reaction chamber 110.

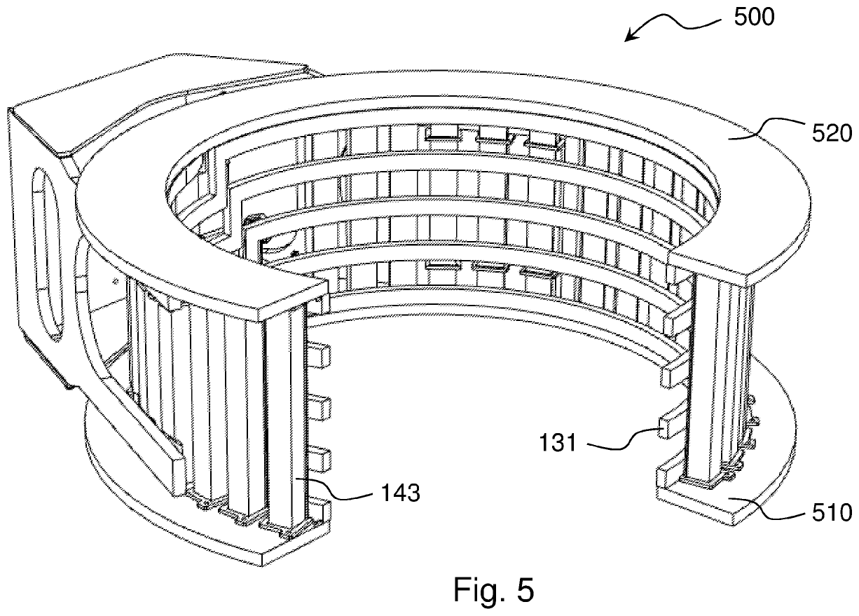

A possible assembly of this kind is shown in FIG. 5; in such a figure, it is assumed reference is made to the assembly 500.

In FIG. 5 it is possible to see the solenoid 131 with its coils (in this example there are five internally hollow coils so as to be able to cool them effectively and simply) and the shield 141 with its bars 143 parallel to one another (in this example there are forty bars). Moreover, the assembly 500 comprises a lower support ring 510 (in particular made of fibreglass) and an upper support ring 520 (in particular made of fibreglass). The solenoid 131 is mechanically fixed to the rings 510 and 520. The bars 143 are mechanically fixed to the rings 510 and 520.

The power supply 135 (more precisely the feeding sections 135A and 135B) is adapted for feeding the inductors 131 and 132 with alternating currents preferably at frequencies comprised between 1 KHz and 10 KHz. The section 135A can supply the inductor 131 for example with an electric power of 20-200 KWatt, and the section 135B can supply the inductor 132 for example with an electric power of 20-200 KWatt; the electric powers supplied to the two inductors are in general different from one another and, typically, change over time.

The alternating currents that flow in the inductors 131 and 132 (caused by the feeding sections 135A and 135B) are preferably at different frequencies; for example, the current that flows in one of the two inductors can be at higher frequency than the current that flows in the other of the two inductors by a factor greater than 1.8 and less than 4.4. The difference in frequency facilitates the task of the feeding sections 135A and 135B of feeding the inductors 131 and 132 independently from one another.

However, through a suitable design of the power supply 135, it is possible for the alternating currents that flow in the inductors 131 and 132 (caused by the power supply 135) to be at the same frequency, but distinct and independent from one another. In particular, the power supply 135 has an outlet for every inductor and such outlets are distinct and independent from one another.

1. Reactor for deposition of layers of semiconductor material on substrates comprising:
a reaction chamber,
a susceptor assembly located inside the reaction chamber, and
a heating system adapted to heat the susceptor assembly by electromagnetic induction;
wherein the heating system comprises a first inductor and a second inductor and a power supply adapted to electrically feed the first and second inductors with alternating currents that are distinct and independent from one another;
the reactor further comprising a shielding assembly adapted to limit electromagnetic coupling between the first and second inductors.

2. Reactor according to claim 1, wherein said shielding assembly comprises a first shield associated with the first inductor and a second shield associated with the second inductor.

3. Reactor according to claim 1, wherein the first and second inductors are solenoids coaxial and axially spaced, and of the same diameter.

4. Reactor according to claim 3, wherein the shielding assembly is tubular shape and is located around one or more solenoids.

5. Reactor according to claim 3, wherein the solenoids are adapted to be translated axially one independently of the other.

6. Reactor according to claim 5, wherein said shielding assembly comprises a first shield associated with the first inductor and a second shield associated with the second inductor, and wherein said shields are adapted to translate together with the corresponding inductors.

7. Reactor according to claim 1, wherein said shielding assembly comprises shielding components of a material having high magnetic permeability, in particular of a ferromagnetic material.

8. Reactor according to claim 7, wherein said material has high electrical resistivity.

9. Reactor according to claim 1, wherein said shielding assembly comprises a first plurality of shielding bars parallel to each other, and a second plurality of shielding bars parallel to each other.

10. Reactor according to claim 9, wherein a layer of electrical insulating material is located on said shielding bars at least on the side of said shielding bars facing an inductor.

11. Reactor according to claim 1, wherein said reaction chamber has a cylindrical or prismatic shape and wherein the reactor comprises at least a first assembly and a second assembly adapted to translate axially along the reaction chamber, wherein each of said assemblies comprises a solenoid, a plurality of parallel shielding bars, a lower support ring and an upper support ring, wherein said solenoid is mechanically fixed to said support rings, and wherein said shielding bars are mechanically fixed to said support rings.

12. Reactor according to claim 1, wherein said power supply is adapted to feed said first and second inductors with alternating currents so that the currents which flow in said first and second inductors are at frequencies included between 1 KHz and 10 KHz.

13. Reactor according to claim 1, wherein said power supply is adapted to feed said first and second inductors with alternating currents so that the currents which flow in said first and second inductors are at the same frequency but distinct and independent from one another.

14. Reactor according to claim 1, wherein said power supply is adapted to feed said first and second inductors with alternating currents so that the current that flows in said first inductor is at a different frequency from the current that flows in said second inductor.

15. Reactor according to claim 14, wherein the current that flows in one of the two inductors is at a higher frequency from the current that flows in the other of the two inductors by a factor greater than 1.8 and smaller than 4.4.
